(19) United States
(12) Patent Application Publication
(10) Pub. No.: US 2024/0330520 A1
(43) Pub. Date: Oct. 3, 2024

(54) RAINWATER TREATMENT METHOD AND RAINWATER TREATMENT SYSTEM APPLIED TO MINE WASTELAND

(71) Applicant: HUBEI UNIVERSITY OF TECHNOLOGY, Wuhan (CN)

(72) Inventors: Guiyuan LI, Wuhan (CN); Guo CHENG, Wuhan (CN); Guanhua CHEN, Wuhan (CN); Zhanneng WU, Wuhan (CN); Xiaoxiao LIU, Wuhan (CN); Biao GUO, Wuhan (CN)

(21) Appl. No.: 18/203,940

(22) Filed: May 31, 2023

(30) Foreign Application Priority Data
Mar. 31, 2023 (CN) 202310332859.1

(51) Int. Cl. G06F 30/10; G06V 20/17

(52) U.S. Cl. CPC G06F 30/10; G06V 20/17

(57) ABSTRACT

Disclosed are a rainwater treatment method and a rainwater treatment system applied to mine wasteland, and the method includes following steps: collecting rainwater data of the mine wasteland, and processing the rainwater data of the mine wasteland to generate rainwater data; extracting parameters from the rainwater data to obtain rainwater parameters; constructing a mine three-dimensional model, and inputting the rainwater parameters into the mine three-dimensional model to generate a visual three-dimensional model; and treating the rainwater in the mine wasteland based on the visual three-dimensional model.

### CROSS-REFERENCE TO RELATED APPLICATIONS

This application claims priority to Chinese Patent Application No. 202310332859.1, filed on Mar. 31, 2023, the contents of which are hereby incorporated by reference.

### TECHNICAL FIELD

The application belongs to a technical field of ecological environment protection, and in particular to a rainwater treatment method and a rainwater treatment system applied to mine wasteland.

### BACKGROUND

Mines have made great contributions to a social development in history. However, after the completion of mining, a large number of abandoned mines lead to an ecological environment deterioration and severely restrict an economic development. Strengthening a mine ecological environment management is an inevitable requirement for promoting the rational development and utilization of resources and the coordination of ecological protection.

At present, the data collection in the rainwater treatment of mine wasteland is mainly based on field survey, but the data cannot be accurately used in rainwater treatment after collecting data. At the same time, the data is collected and then equipment directly is installed directly for rainwater treatment without using data, which results in a waste of resources, and at the same time, the real-time monitoring of the rainwater data in mine wasteland is not possible.

### SUMMARY

The purpose of the application is to provide a rainwater treatment method and a rainwater treatment system applied to mine wasteland, so as to solve the problems existing in the prior art.

In order to achieve the above purpose, the application provides a rainwater treatment method applied to the mine wasteland, including following steps:
collecting rainwater data of the mine wasteland, and processing the rainwater data of the mine wasteland to generate rainwater data;
extracting parameters from the rainwater data to obtain rainwater parameters;
constructing a mine three-dimensional model, and inputting the rainwater parameters into the mine three-dimensional model to generate a visual three-dimensional model; and
treating the rainwater in the mine wasteland based on the visual three-dimensional model.

Optionally, a process of generating the rainwater data includes:
acquiring rainfall data of the mine wasteland based on sensors;
acquiring environmental image data of the mine wasteland based on an unmanned aerial vehicle; and
extracting features from the rainfall data and the environmental image data to generate the rainwater data;
optionally, a process of acquiring the rainwater parameters includes:
acquiring optimized regional target index based on terrains and a total runoff of the mine wasteland;
acquiring rainwater collection parameters based on the rainwater data;
generating the rainwater parameters based on the optimized regional target index and the rainwater collection parameters;
the terrains and the total runoff of the mine wasteland are obtained based on measurement;
the rainwater parameters include a recoverable rainwater flow, an initial rainwater discharge quantity, the total runoff, the rainwater collection parameters, a water pressure, a lift and flow parameters.

Optionally, a process of generating the visual three-dimensional model includes:
establishing a mine building information model (BIM) three-dimensional model; and
matching the rainwater parameters with the mine BIM three-dimensional model to obtain a visual three-dimensional model.

Optionally, a process of treating the rainwater in the mine wasteland based on the visual three-dimensional model includes:
installing a liquid level sensor based on the visual three-dimensional model, and constructing a reservoir to obtain rainwater to be treated;
treating the rainwater to be treated based on a separated rainwater processor to obtain purified rainwater.

The application also provides a rainwater treatment system applied to mine wasteland, including:
a data collection module used for collecting rainwater data of the mine wasteland and processing the rainwater data of the mine wasteland to generate a rainwater data set;
a data calculation module connected with the data collection module and used for extracting the parameters from the rainwater data to obtain the rainwater parameters;
a model construction module connected with the data calculation module and used for constructing the visual three-dimensional model based on the rainwater parameters; and
a processing module connected with the model construction module and used for treating the rainwater in the mine wasteland based on the visual three-dimensional model.

Optionally, the data collection module includes:
a rainwater collection unit used for acquiring the rainwater data of the mine wasteland;
an image acquisition unit used for acquiring the environmental image data of the mine wasteland; and
a feature extraction unit used for extracting features from the rainfall data and the environmental image data to generate a rainwater data set.

Optionally, the model construction module includes:
a modeling unit used for establishing the mine three-dimensional model based on BIM technology; and
a data matching unit, used for matching the rainwater parameters with the mine BIM three-dimensional model to obtain the visual three-dimensional model.

Optionally, the processing module includes:
an anomaly acquisition unit used for acquiring rainwater storage positions of the mine wasteland and acquiring a water storage area to be treated; and
a rainwater treatment unit, used for treating rainwater based on the water storage area to be treated to obtain the purified rainwater.

The application has following technical effects:
First, a three-dimensional visualization model of the mine wasteland is established, and the rainwater in mine may be visualized more effectively;
second, the rainwater parameters of the mine wasteland are obtained and matched with the three-dimensional model, and the rainwater data may be accurately identified and processed in time; and
third, the mine three-dimensional model is established based on the BIM technology, and the treatment of mine rainwater may be predicted based on the time.

### BRIEF DESCRIPTION OF THE DRAWINGS

The accompanying drawings, which constitute a part of this application, are used to provide a further understanding of this application. The illustrative embodiments of this application and corresponding descriptions are used to explain this application, and do not constitute an improper limitation of this application. In the attached drawings:

FIG. 1 is a flowchart of a rainwater treatment method in an embodiment of the present application.

FIG. 2 is a schematic diagram of a rainwater treatment system in an embodiment of the present application.

### DETAILED DESCRIPTION

It should be noted that the embodiments in this application and the features in the embodiments may be combined with each other without conflict. The present application will be described in detail with reference to the attached drawings and embodiments.

It should be noted that the steps shown in the flowchart of the accompanying drawings may be executed in a computer system such as a set of computer-executable instructions, and although the logical order is shown in the flowchart, in some cases, the steps shown or described may be executed in a different order from here.

### Embodiment 1

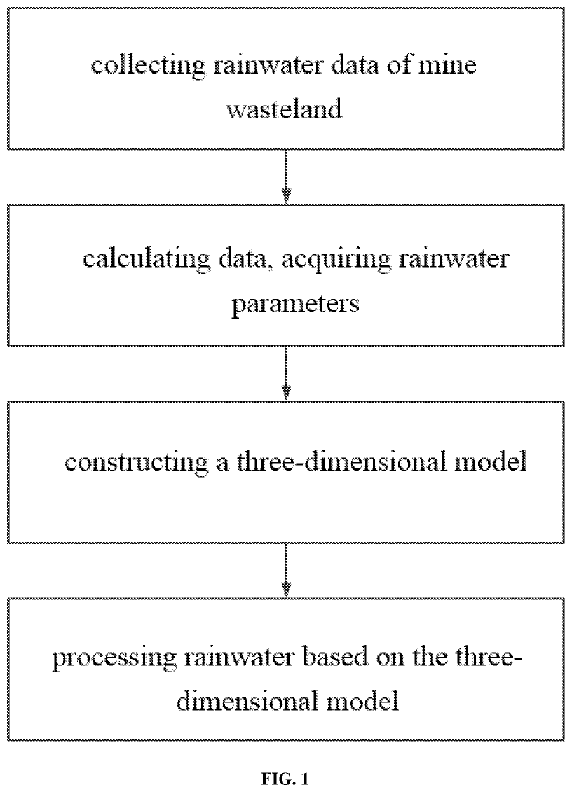

As shown in FIG. 1, this embodiment provides a rainwater treatment method applied to mine wasteland, including:
collecting rainwater data of the mine wasteland, and processing the rainwater data of the mine wasteland to generate a rainwater data set;
extracting parameters from the rainwater data to obtain rainwater parameters;
constructing a mine three-dimensional model, and inputting the rainwater parameters into the mine three-dimensional model to generate a visual three-dimensional model; and
treating the rainwater in the mine wasteland based on the visual three-dimensional model.

In another embodiment, the process of generating the rainwater data set includes:
acquiring rainwater data of the mine wasteland based on sensors;
acquiring environmental image data of the mine wasteland based on an unmanned aerial vehicle;
the unmanned aerial vehicle includes an unmanned aerial vehicle with a tripod, a mounting bracket is fixed and arranged at the bottom of the unmanned aerial vehicle, a mounting plate suspended on the mounting bracket through a damping mechanism and placed inside the tripod, and a digital camera placed at the opening and horizontally fixed on the mounting plate, where the unmanned aerial vehicle is provided with a position and orientation system (POS) data acquisition module.

Where position data are acquired as an initial value of POS data of the unmanned aerial vehicle through a global navigation satellite system (GNSS), an attitude change increment is obtained through an inertial measurement unit (IMU), and an iterative operation is controlled by a Kalman filter and feedback errors to generate real-time navigation data.

Extracting features from the rainfall data and the environmental image data to generate a rainwater data set;
the rainwater data includes rainfall data and total runoff data.

In another embodiment, a process of acquiring the rainwater parameters includes:
acquiring optimized regional target index based on terrains and a total runoff of the mine wasteland;
calculating rainwater collection parameters based on the rainwater data set;
generating the rainwater parameters based on the optimized regional target index and the rainwater collection parameters;
the rainwater parameters include a recoverable rainwater flow, an initial rainwater discharge quantity, the total runoff, the rainwater collection parameters, a water pressure, a lift and flow parameters.

In another embodiment, a process of generating the visual three-dimensional model includes:
establishing a mine BIM three-dimensional model; and
matching the rainwater parameters with the mine BIM three-dimensional model to obtain a visual three-dimensional model.

In another embodiment, a process of treating the rainwater in the mine wasteland based on the visual three-dimensional model includes:
installing a liquid level sensor based on the visual three-dimensional model, and constructing a reservoir to obtain rainwater to be treated;
treating the rainwater to be treated based on a separated rainwater processor to obtain purified rainwater, and a process of purifying rainwater is as follows:
(1) Screens and grates. Because rainwater contains coarse floating objects and suspended substances, such as leaves, peels, fibers, etc., in order to reduce subsequent treatment loads, grates or screens are used to intercept them. Grates are made of metal bars, may be directly welded by profile steels, and are mainly made of thin grates (with a bar spacing of 2 millimeters-5 millimeters); the screens are made of plane strip filter screens, placed obliquely or flatly, and the interval of filter screens should be between 0.5 millimeters-2 millimeters.
(2) Coagulation and a sedimentation. For treating rainwater with high suspended solids content, a coagulation equipment is helpful to improve a subsequent treatment efficiency. In this embodiment, the coagulation is an aggregation process of colloidal particles and tiny suspended solids in water. The coagulant is aluminum salt, iron salt or polyelectrolyte, and coagulant aids are quicklime, activated silicic acid, etc. The coagulant in liquid state is added, and the solid is dissolved to prepare a solution with a certain concentration and put into water. The sedimentation is the most suitable way to remove sediments and suspended matters in rainwater, and a horizontal sedimentation tank is recommended, which is easy to build and has high sedimentation efficiency. The minimum residence time of rainwater in the sedimentation tank is no more than 2 minutes. In this embodiment, the cleaner rainwater may remove 70% of suspended matters and 40% of organic pollutants after sedimentation, and may be directly reused for green space irrigation. For rainwater with serious pollution such as road runoff, the coagulation and the sedimentation may remove 60%-80% of pollutants, but a further filtration treatment is still needed.
(3) Filtration. The purpose of filtration in this embodiment is to further remove remaining suspended solids, colloidal substances, turbidity and organic matters in the pretreatment, and improve the effluent quality. the initial rainwater should be removed in the rainwater treatment during the filtration, otherwise the filter tank will be easily blocked. For road runoffs, a precipitation process is also added during the filtration in this embodiment. Rainwater filter tanks are designed with a single-layer filter tank and a double-layer filter tank. Fine sand may be the filter material of the single-layer filter tank, the particle size of the filter material is 0.5 millimeters-1.2 millimeters, and the thickness of the filter layer is 80 millimeters-120 millimeters. Anthracite and fine sand are used as the filter materials of the double-layer filter tank, and the particle size and thickness of the filter materials are close to those of the single-layer filter tank.

### Embodiment 2

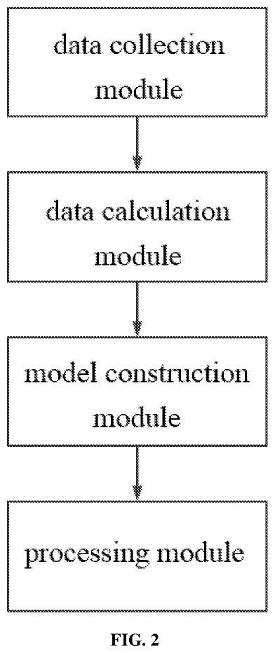

As shown in FIG. 2, this embodiment provides a rainwater treatment system applied to mine wasteland, including:
a data collection module used for collecting rainwater data of the mine wasteland and processing the rainwater data of the mine wasteland to generate a rainwater data set;
a data calculation module connected with the data collection module and used for extracting the parameters from the rainwater data to obtain the rainwater parameters;
a model construction module connected with the data calculation module and used for constructing the visual three-dimensional model based on the rainwater parameters; and
a processing module connected with the model construction module and used for treating the rainwater in the mine wasteland based on the visual three-dimensional model. In this embodiment, a reservoir is established to store the rainwater, and crops are planted in the mine wasteland to restore the ecological environment.

Specifically, in this embodiment, before the reservoir is built, the water outlet point of the four seasons seepage layer in the mine is checked, and the naturally formed gullies and running water ditches are checked; the water seepage and annual precipitation are calculated, and providing a data support for the construction of flood discharge buffer lake. This kind of work provides a theoretical support for the subsequent planting. The flood discharge buffer lake is built near seepage points, with a low terrain, a stable geology and a large area (meeting the requirements of maximum water storage).

Specifically, because the flood discharge buffer lake is a simple water storage facility, it is not necessary to make the bottom super-flat, and it may be paved with matrix soil according to the original terrain of the mine. The matrix soil includes organic fertilizer and original soil, and the volume ratio of the organic fertilizer to the original soil is 1: 4-6; optionally, the spreading thickness of the matrix soil is 10 centimeters-20 centimeters. In this embodiment, the combination of organic fertilizer and original soil makes full use of local raw materials on the one hand, and may provide nutrients for plant growth on the other hand. If the amount of organic fertilizer is too much, the construction cost will be greatly increased; for example, if the amount of organic fertilizer is too small, the original soil basically contains no nutrients for plant growth, which directly leads to poor landscape effect and unsatisfactory prevention and control effect of soil erosion; the amount of organic fertilizer is also coordinated with planting density, planting crops and other factors, which may provide nutrients for crops for about one year. After one year, due to the growth of leguminous plants and the metabolism of plants, the nutrients in the matrix soil may meet the growth needs of crops.

Specifically, the organic fertilizer may be phosphate fertilizer and nitrogen fertilizer for plant growth, and may also be compound fertilizer purchased in the market. Organic fertilizer may provide nitrogen, phosphorus, potassium and microorganisms for plant growth, and may adjust soil pH value.

Optionally, the sowing time of saline-alkali tolerant plants and emergent floating plants is from early May to early June; optionally from May 13th to May 18th. It is found out that it is most suitable to plant crops in mid-May, because the water content in the wetland and aquatic plants growing environment is relatively high and the ground temperature in early spring is relatively low, so the necessary ground temperature for ensuring plant germination is appropriate in mid-May.

Specifically, the saline-alkali tolerant plants include Lolium perenne, Elymus dahuricus Turcz, Leymus chinensis, Hippophae rhamnoides and Artemisia desertorum, and the sowing density of the saline-alkali tolerant plants is 10-30 kilograms/mu (1 mu=666.67 square meters). Due to the serious evaporation above the normal water level, the salt concentration in this area is high. The above saline-alkali tolerant plants are more suitable for planting in the area above the normal water level of the mine, which may form a natural landscape with good ornamental value and effectively prevent the occurrence of soil erosion.

In another embodiment, the data collection module includes:
a rainwater collection unit used for acquiring the rainwater data of the mine wasteland;
an image acquisition unit used for acquiring the environmental image data of the mine wasteland; and
a feature extraction unit used for extracting features from the rainfall data and the environmental image data to generate a rainwater data set.

In another embodiment, the model construction module includes:
a modeling unit used for establishing the mine three-dimensional model based on BIM technology; and
a data matching unit used for matching the rainwater parameters with a mine BIM three-dimensional model to obtain the visual three-dimensional model.

In another embodiment, the processing module includes:
an anomaly acquisition unit used for acquiring rainwater storage positions of the mine wasteland and acquiring a water storage area to be treated; and
a rainwater treatment unit used for treating rainwater based on the water storage area to be treated to obtain the purified rainwater.

The above is only the preferred embodiment of this application, but the protection scope of this application is not limited to this. Any change or replacement that may be easily thought of by a person familiar with this technical field within the technical scope disclosed in this application should be covered by this application. Therefore, the protection scope of this application should be based on the protection scope of the claims.

What is claimed is:

1. A rainwater treatment method applied to mine wasteland, comprising following steps:
collecting rainwater data of the mine wasteland, and processing the rainwater data of the mine wasteland to generate rainwater data;
extracting parameters from the rainwater data to obtain rainwater parameters;
constructing a mine three-dimensional model, and inputting the rainwater parameters into the mine three-dimensional model to generate a visual three-dimensional model; and
treating the rainwater in the mine wasteland based on the visual three-dimensional model.

2. The rainwater treatment method applied to mine wasteland according to claim 1,
wherein a process of generating rainwater data comprises:
acquiring rainfall data of the mine wasteland based on sensors;
acquiring environmental image data of the mine wasteland based on an unmanned aerial vehicle; and
extracting features from the rainfall data and the environmental image data to generate the rainwater data.

3. The rainwater treatment method applied to mine wasteland according to claim 1, wherein a process of acquiring the rainwater parameters comprises:
acquiring optimized regional target index based on terrains and a total runoff of the mine wasteland;
acquiring rainwater collection parameters based on the rainwater data;
generating the rainwater parameters based on the optimized regional target index and the rainwater collection parameters;
wherein the terrains and the total runoff of the mine wasteland are obtained based on measurement; and
the rainwater parameters comprise a recoverable rainwater flow, an initial rainwater discharge quantity, a total runoff, rainwater collection parameters, a water pressure, a lift and flow parameters.

4. The rainwater treatment method applied to mine wasteland according to claim 1, wherein a process of generating the visual three-dimensional model comprises:
establishing a mine building information model (BIM) three-dimensional model; and
matching the rainwater parameters with the mine BIM three-dimensional model to obtain the visual three-dimensional model.

5. The rainwater treatment method applied to mine wasteland according to claim 1, wherein a process of treating the rainwater in the mine wasteland based on the visual three-dimensional model comprises:
installing a liquid level sensor based on the visual three-dimensional model, and constructing a reservoir to obtain rainwater to be treated; and
treating the rainwater to be treated based on a separated rainwater processor to obtain purified rainwater.

6. A rainwater treatment system applied to mine wasteland, comprising:
a data collection module used for collecting rainwater data of the mine wasteland, and processing the rainwater data of the mine wasteland to generate a rainwater data set;
a data calculation module connected with the data collection module and used for extracting the parameters from the rainwater data to obtain the rainwater parameters;
a model construction module connected with the data calculation module and used for constructing the visual three-dimensional model based on the rainwater parameters; and
a processing module connected with the model construction module and used for treating the rainwater in the mine wasteland based on the visual three-dimensional model.

7. The rainwater treatment system applied to mine wasteland according to claim 6, wherein the data collection module comprises:
a rainwater collection unit used for acquiring the rainwater data of the mine wasteland;
an image acquisition unit used for acquiring the environmental image data of the mine wasteland; and
a feature extraction unit used for extracting features from the rainfall data and the environmental image data to generate a rainwater data set.

8. The rainwater treatment system applied to mine wasteland according to claim 6, wherein the model construction module comprises:
a modeling unit used for establishing the mine three-dimensional model based on BIM technology; and
a data matching unit used for matching the rainwater parameters with the mine BIM three-dimensional model to obtain the visual three-dimensional model.

9. The rainwater treatment system applied to mine wasteland according to claim 6, wherein the processing module comprises:
an anomaly acquisition unit used for acquiring rainwater storage positions of the mine wasteland and acquiring a water storage area to be treated; and
a rainwater treatment unit used for treating rainwater based on the water storage area to be treated to obtain purified rainwater.
